(19) United States
(12) Patent Application Publication
(10) Pub. No.: US 2010/0171151 A1
(43) Pub. Date: Jul. 8, 2010

(54) HETEROJUNCTION BIPOLAR TRANSISTOR AND MANUFACTURING METHOD THEREOF

(75) Inventors: Kenichi MIYAJIMA, Toyama (JP); Akiyoshi TAMURA, Osaka (JP); Keiichi MURAYAMA, Toyama (JP); Hirotaka MIYAMOTO, Toyama (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/648,406

(22) Filed: Dec. 29, 2009

(30) Foreign Application Priority Data
Jan. 6, 2009 (JP) 2009-001174
Jul. 9, 2009 (JP) 2009-163114

(51) Int. Cl. H01L 29/737; H01L 21/331

(52) U.S. Cl. 257/197; 438/312; 257/E29.188; 257/E21.371

(57) ABSTRACT

An HBT according to this invention includes: a sub-collector layer; a collector layer formed on the sub-collector layer and the base layer including a first collector layer, a second collector layer, a third collector layer, and a fourth collector layer. The first collector layer is formed on the sub-collector layer, and is made of semiconductor different from semiconductor of which the second to the fourth collector layers are made. The fourth collector layer is formed on the first collector layer, and has an impurity concentration lower than an impurity concentration of the second collector layer. The second collector layer is formed on the fourth collector layer, and has an impurity concentration lower than an impurity concentration of the sub-collector layer and higher than an impurity concentration of the third collector layer. The third collector layer is formed between the second collector layer and the base layer.

### BACKGROUND OF THE INVENTION

(1) Field of the Invention

The present invention relates to heterojunction bipolar transistors, and particularly relates to an InGaP/GaAs heterojunction transistor.

(2) Description of the Related Art

Heterojunction bipolar transistors (HBT) using semiconductors with large bandgap as emitter have been in practical use as radio-frequency analog devices used for mobile phones and others. More specifically, since there is large discontinuity (ΔEv) in the valence band, the InGaP/GaAs HBT using InGaP for emitter has small temperature dependence in its forward current gain (HFE). For this reason, the InGaP/GaAs HBT is expected to be used for wider range of purposes as a highly reliable device.

It should be noted that the usage of InGaP/GaAs HBTs has been expanding in recent years. For example, even if the example here is limited to the usage for transmission amplifiers of mobile phones, practical use of InGaP/GaAs HBTs as power devices in the terminal transmission units for, not just the conventional the Code Division Multiple Access (CDMA), but also for the Global System for Mobile Communications (GSM) has been considered.

However, when used for the GSM, it is required for the HBTs to have higher tolerance for over input and load fluctuation, compared to the use in the CDMA. For example, the breakdown tolerance level required for the Wideband Code Division Multiple Access (WCDMA) is to achieve the Voltage Standing Wave Ratio (VSWR)=8:1, when Vs=4.2 V. Meanwhile, the breakdown tolerance level required for the GSM is to achieve VSWR=10:1, when Vs=4.5 V. Here, the VSWR denotes voltage standing wave ratio, which is one of the indices indicating high-frequency property of circuits and cables.

As described above, it is required for the HBT used in the GSM to have higher breakdown-tolerant property. Accordingly, it is essential for InGaP/GaAs HBTs to satisfy the breakdown tolerance level when applied to transmission amplifiers for the GSM. However, with the conventional InGaP/GaAs HBT technology, the required breakdown tolerance level is not achieved.

In response to the request for high breakdown-tolerant property of the HBTs, there have been several proposals for improving the breakdown-tolerant property of the HBTs (for example, see Patent Reference 1: Japanese Unexamined Patent Application Publication No. 2007-173624). The following describes the proposal with reference to FIG. 4.

FIG. 4 is a cross-section diagram showing the structure of a conventional HBT with high breakdown-tolerant property.

FIG. 4 shows the HBT 200. The sub-collector layer 202, the collector layer 211, the base layer 207, the emitter layer 208, the emitter-cap layer 209 and the emitter-contact layer 210 are sequentially stacked on the substrate 201 made of semi-insulating GaAs.

The collector layer 211 has a three-layered structure including the first collector layer 203 contacting the sub-collector layer 202, the second collector layer 205 formed on the first collector layer 203, and the third collector layer 206 which is non-doped or of low-impurity concentration and contacting the base layer 207. The first collector layer 203 is made of semiconductor different from that of the second collector layer 205 and the third collector layer 206. The second collector layer 205 is made of semiconductor having lower impurity concentration than that of the first collector layer 203, and higher impurity concentration than that of the third collector layer 206.

Furthermore, in the HBT 200, the emitter electrode 251 is formed on the emitter contact layer 210, the base electrode 252 is formed on the emitter layer 208, and the collector electrode 253 is formed on the sub-collector layer 202.

Furthermore, in the HBT 200, the device isolation region 254 is formed at the device peripheral region of the substrate 201 and the sub-collector layer 202.

### SUMMARY OF THE INVENTION

However, the HBT 200 shown in Patent Reference 1 cannot satisfy the breakdown tolerance level required for the GSM. The following is the description.

FIG. 5 is a chart showing a simulation result of field intensity of the structure of the conventional HBT. In this simulation, the base layer 207 is a p-type GaAs layer of 100 nm in thickness and at an impurity concentration of approximately 4×10¹⁹ cm⁻³, and the first collector layer 203 is an n-type InGaP layer of 30 nm in thickness and at an impurity concentration of approximately 5×10¹⁸ cm⁻³. Furthermore, the second collector layer 205 is an n-type GaAs layer of 400 nm in thickness and at a medium impurity concentration of 1×10¹⁷ cm⁻³, and the third collector layer 206 is an n-type GaAs layer of 600 nm in thickness and at an impurity concentration of 1×10¹⁶ cm⁻³. Furthermore, the sub-collector layer 202 is an n-type GaAs layer of 600 nm in thickness and at an impurity concentration of 5×10¹⁸ cm⁻³.

As shown in FIG. 5, the electric field in the HBT 200 is concentrated on the interface between the base layer 207 and the third collector layer 206, and the interface between the second collector layer 205 and the first collector layer 203.

The structure of the HBT 200 described above is effective for reducing the electric field on the entire collector layer 211, and is effective for the breakdown-tolerant property. However, the second collector layer 205 is a layer with medium impurity concentration, which is more likely to cause an avalanche breakdown than a layer with a low impurity concentration. More specifically, in the field intensity distribution shown in FIG. 5, the electric field on the interface between the second collector layer 205 and the first collector layer 203 causes breakdown on the interface between the second collector layer 205 and the first collector layer 203. Here, the avalanche breakdown refers to a phenomenon where the collector current drastically increases at specific collector-emitter voltage. Note that this phenomenon occurs when reverse bias between the collector and the base intensifies, and the field intensity becomes extremely high. The electrons running in the collector layer at high speed collide with the surrounding atoms, generating electrons and holes.

For this reason, the HBT 200 shown in Patent Reference 1 cannot satisfy the breakdown tolerance level required for the GSM.

The present invention is conceived in light of this problem, and it is an object of the present invention to provide a highly breakdown-tolerant heterojunction bipolar transistor and a manufacturing method thereof.

In order to achieve the abovementioned object, the heterojunction bipolar transistor according to an aspect of the present invention is a heterojunction bipolar transistor including: a sub-collector layer; a collector layer formed on the sub-collector layer and including a first collector layer, a second collector layer, a third collector layer, and a fourth collector layer; a base layer formed on the collector layer; and an emitter layer formed on the base layer, the emitter layer being made of semiconductor that has a bandgap larger than semiconductor of which the base layer is made, in which the first collector layer is formed on the sub-collector layer, the first collector layer being made of semiconductor different from semiconductor of which the second collector layer, the third collector layer, and the fourth collector layer are made, the fourth collector layer is formed on the first collector layer, the fourth collector layer having an impurity concentration lower than an impurity concentration of the second collector layer, the second collector layer is formed on the fourth collector layer, the second collector layer having an impurity concentration lower than an impurity concentration of the sub-collector layer and higher than an impurity concentration of the third collector layer, and the third collector layer is formed between the second collector layer and the base layer.

Here, the first collector layer may be made of InGaP and has an impurity concentration equal to or higher than the impurity concentration of the sub-collector layer, and the second collector layer, the third collector layer, and the fourth collector layer may be made of GaAs.

With this structure, the layer contacting the first collector layer is the fourth collector layer which has the impurity concentration lower than that of the second collector layer. This suppresses the avalanche breakdown occurring on the interface between the fourth collector layer and the first collector layer.

This allows the heterojunction bipolar transistor according to an aspect of the present invention to achieve higher breakdown-tolerant property than the heterojunction bipolar transistor with conventional structure described above.

Furthermore, with this structure, the impurity concentration of the first collector layer can be set high, for example, in the 10^{18th} order, lowering the resistance of the first collector layer. This allows increasing the breakdown voltage, without increasing the collector resistance. Furthermore, the first collector layer functions as an etching stopper layer when manufacturing, and thus it is possible to raise the yield.

Furthermore, the fourth collector layer may have a thickness of 50 nm or less.

With this structure, there will be little increase in resistance caused by the fourth collector layer, and thus it is possible to improve the breakdown-tolerant property without characteristic degradation.

Furthermore, the fourth collector layer may have a thickness of 1 nm or more.

This structure more effectively improves the breakdown-tolerant property than the case where the thickness of the fourth collector layer is less than 1 nm.

Furthermore, the first collector layer may be made of InGaP having a disordered structure.

This structure increases the doping efficiency of InGaP, and raises the impurity concentration of the first collector layer. Accordingly, it is possible to lower the resistance of the first collector layer. Furthermore, it is possible to prevent the location of carriers in InGaP. Thus, it is possible to suppress the electric intensity concentration, and improve the breakdown-tolerant property of the heterojunction bipolar transistor.

Furthermore, the first collector layer may have a thickness between 5 nm and 50 nm, inclusive.

With this structure, there will be little increase in resistance caused by the first collector layer, and thus it is possible to improve the breakdown-tolerant property without characteristic degradation and raise the yield.

Furthermore, the impurity concentration of the second collector layer ranges from 3×10¹⁶ cm⁻³ to 2×10¹⁷ cm⁻³, and the impurity concentration of the third collector layer is lower than 3×10¹⁶ cm⁻³.

This structure effectively eases the electric intensity concentration.

Furthermore, the second collector layer may have a thickness of 400 nm or more, and the third collector layer may have a thickness of 600 nm or less.

This structure effectively eases the electric intensity concentration.

Furthermore, the first collector layer may be made of two or more layers having different impurity concentrations. For example, the first collector layer may be formed of layers including an InGaP layer contacting the sub-collector layer and is non-doped or doped, and a semiconductor layer having an impurity concentration higher than the impurity concentration of the InGaP layer on the InGaP layer (in the direction of the second collector layer).

This structure reduces δEc, achieving a high-performance heterojunction bipolar transistor.

Furthermore, in order to achieve the abovementioned object, the manufacturing method of the heterojunction bipolar transistor according to an aspect of the present invention is a manufacturing method of a heterojunction bipolar transistor, the manufacturing method including: stacking a sub-collector layer, a collector layer that includes: a first collector layer; a second collector layer; a third collector layer; and a fourth collector layer, a base layer, and an emitter layer, sequentially on a semiconductor substrate; and etching a part of: the emitter layer; the base layer; and the collector layer, such that a region on the sub-collector layer for forming a collector electrode is exposed; in which, in the stacking, the first collector layer is formed on the sub-collector layer, the first collector layer being made of semiconductor different from semiconductor of which the second collector layer, the third collector layer, and the fourth collector layer are made, the fourth collector layer is stacked on the first collector layer, the fourth collector layer having an impurity concentration lower than an impurity concentration of the second collector layer, the second collector layer is stacked on the fourth collector layer, the second collector layer having an impurity concentration lower than an impurity concentration of the sub-collector layer and higher than an impurity concentration of the third collector layer, the third collector layer is stacked between the second collector layer and the base layer, and the emitter layer is stacked on the base layer, the emitter layer being made of semiconductor with larger bandgap than semiconductor of which the base layer is made. Here, it is preferable that, in the etching, a part of the first collector layer is etched using an etchant different from an etchant used for etching the third collector layer, the second collector layer, and the fourth collector layer, after etching a part of: the third collector layer; the second collector layer; and the fourth collector layer.

According to this manufacturing method, the first collector layer can be made of the semiconductor having etching selectivity on the third collector layer and the second collector layer. This allows the first collector layer to function as an etching stopper layer when etching the collector layer, and thus it is possible to increase the workability upon etching, and to manufacture the heterojunction bipolar transistor with at high reproducibility and high yield.

The present invention allows a heterojunction bipolar transistor with high breakdown-tolerant property and its manufacturing method.

More specifically, it is possible to manufacture a heterojunction bipolar transistor with high breakdown-tolerant property compared to the conventional InGaP/GaAs heterojunction bipolar transistor. With the present invention, the InGaP/GaAs HBT shows new possibility as a power amplifier in the termination transmission unit in the GSM. Therefore, the practical value of the present invention is extremely high.

### FURTHER INFORMATION ABOUT TECHNICAL BACKGROUND TO THIS APPLICATION

The disclosure of Japanese Patent Applications No. 2009-001174 filed on Jan. 6, 2009 and No. 2009-163114 filed on Jul. 9, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional diagram showing the structure of HBT according to the embodiment of the present invention;

FIG. 2 is a chart showing a result of experiment on the breakdown voltages of the HBT according to the present invention and the conventional HBT;

FIG. 3A is a cross-sectional diagram showing a manufacturing method of the HBT according to the embodiment of the present invention;

FIG. 3B is a cross-sectional diagram showing a manufacturing method of the HBT according to the embodiment of the present invention;

FIG. 3C is a cross-sectional diagram showing a manufacturing method of the HBT according to the embodiment of the present invention;

FIG. 3D is a cross-sectional diagram showing a manufacturing method of the HBT according to the embodiment of the present invention;

FIG. 4 is a cross-sectional diagram showing the structure of conventional HBT; and

FIG. 5 is a chart showing a result of field intensity simulation with the conventional HBT.

### DESCRIPTION OF THE PREFERRED EMBODIMENT(S)

The following is the detailed description of the heterojunction bipolar transistor according to the embodiment of the present invention.

### First Embodiment

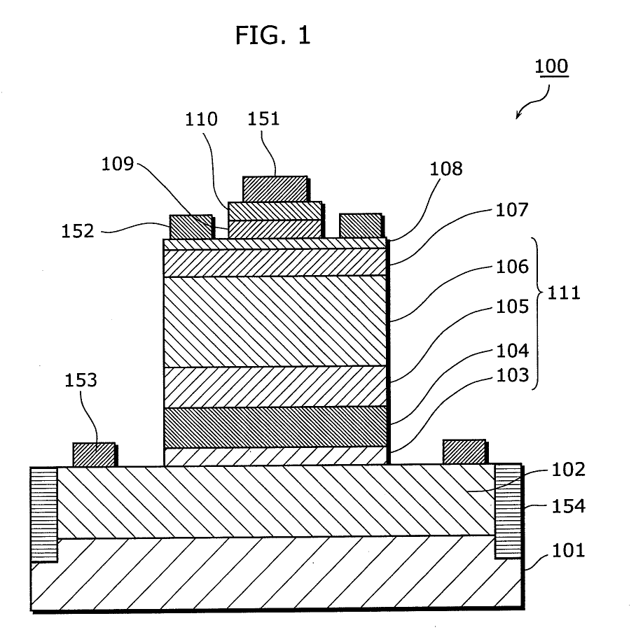

FIG. 1 is a cross-sectional diagram showing the structure of the HBT according to the present invention.

In the HBT 100 shown in FIG. 1, the sub-collector 102 made of n⁺-type GaAs doped with n-type impurity at a high concentration of 5×10¹⁸ cm⁻³ is formed on the substrate 101 made of semi-insulating GaAs. The collector layer 111 doped with the n-type impurity is formed on the sub-collector layer 102. The base layer 107 made of p-type GaAs of 100 nm in thickness, doped with the impurity and a high concentration of 4×10¹⁹ cm⁻³ is formed on the collector layer 111. The emitter layer 108 made of n-type InGaP of 50 nm in thickness, doped with the n-type impurity at an impurity concentration of 3×10¹⁷ cm⁻³ is formed on the base layer 107.

The collector layer 111, the base layer 107, and the emitter layer 108 are processed to form a convex-shape isolating the base region, and to form a base island region.

Furthermore, in the HBT 100, on the emitter layer 108, the emitter cap layer 109 made of GaAs of 200 nm in thickness, doped with n-type impurity at an impurity concentration of 3×10¹⁸ cm⁻³ and the emitter contact layer 110 made of InGaAs of 100 nm in thickness, doped with n-type impurity at an impurity concentration of 1×10¹⁹ cm⁻³ are stacked to have a convex-shape, and to form the emitter island region.

Furthermore, in the HBT 100, on a collector window formed in a region where the sub-collector layer 102 is exposed, a collector electrode 153 made of AuGe/Ni/Au and the like is formed by evaporation. In addition, on the emitter contact layer 110, the emitter electrode 151 made of Pt/Ti/Pt/Au and the like is formed. In a region where the emitter layer 108 is exposed around the emitter cap layer 109, the base electrode 152 made of Pt/Ti/Pt/Au and the like is formed by diffusing Pt/Ti/Pt/Au and the like with heat from the emitter layer 108 so as to make ohmic contact with the base layer 107.

The collector layer 111 is formed of the first collector layer 103 formed on the sub-collector layer 102, the fourth collector layer 104 formed on the first collector layer 103, the second collector layer 105 formed on the fourth collector layer 104, and the third collector layer 106 formed between the second collector layer 105 and the base layer 107.

Here, the first collector layer 103 is made of semiconductor which is different from semiconductors forming the third collector layer 106, the second collector layer 105, and the fourth collector layer 104. For example, the first collector layer 103 is made of n-type InGaP having a disordered structure and of 30 nm in thickness, doped with the n-type impurity at a high impurity concentration of 5×10¹⁸ cm⁻³. As described above, the first collector layer 103 is made of n-type InGaP, and has an impurity concentration equal to or higher than the impurity concentration of the sub-collector layer 102. Note that, the disordered structure refers to a structure where atoms are irregularly arranged.

Furthermore, the first collector layer may have a thickness between 5 nm and 50 nm, inclusive. In this embodiment, the thickness of the first collector layer 103 is 30 nm.

Furthermore, the second collector layer 105 is made of semiconductor having an impurity concentration lower than the impurity concentration of the sub-collector layer 102, and higher than the impurity concentration of the third collector layer 106. For example, the second collector layer 105 is made of n-type GaAs of 400 nm in thickness, doped at an impurity concentration of 1×10¹⁷ cm⁻³.

Note that, the impurity concentration of the second collector layer 105 may be between 3×10¹⁶ cm⁻³ and 2×10¹⁷ cm⁻³, and the thickness of the second collector layer 105 may be 400 nm or more, in order to effectively ease the electric intensity concentration.

Furthermore, the third collector layer 106 is made of semiconductor having an impurity concentration lower than the impurity concentration of the second collector layer 105. For example, the third collector layer 106 is made of n-type GaAs or non-doped i-type GaAs of 600 nm in thickness, doped at an impurity concentration of 1×10¹⁶ cm⁻³.

Note that, the third collector layer 106 may be formed with two or more layers having different impurity concentration. In addition, the impurity concentration of the third collector layer 106 may gradually increase from the interface with the base layer 107 to the interface with the second collector layer 105.

Furthermore, the impurity concentration of the third collector layer 106 may be lower than 3×10¹⁶ cm⁻³ to effectively ease the electric intensity concentration in the HBT 100. Furthermore, the thickness of the third collector layer 106 may be 600 nm or less.

Furthermore, the fourth collector layer 104 is made of semiconductor having an impurity concentration lower than the impurity concentration of the second collector layer 105. For example, the fourth collector layer 104 is made of n-type GaAs of 5 nm in thickness, doped at an impurity concentration of 1×10¹⁶ cm⁻³.

Note that, the thickness of the fourth collector layer 104 may only have to be 1 nm or more and 50 nm and less, in order to improve the breakdown-tolerant property of the HBT 100 more effectively. In this embodiment, the thickness of the fourth collector layer 104 is 5 nm.

Furthermore, the fourth collector layer 104 may be formed of two or more layers having different impurity concentrations. In addition, the impurity concentration of the fourth collector layer 104 may gradually decrease from the interface with the second collector layer 105 to the interface with the first collector layer 103.

The structure of the HBT 100 according to the present invention is as described above.

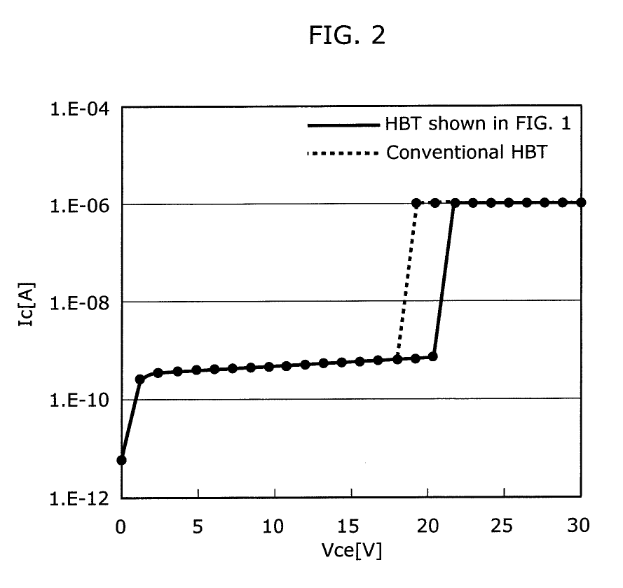

FIG. 2 is a chart showing a result of experiment on the breakdown voltages of the HBT according to the present invention and the conventional HBT. FIG. 2 shows the dependence of Ic-Vce, with the collector current Ic as the vertical axis and the collector-emitter voltage Vce as the horizontal axis.

As shown in FIG. 2, Vce at the time of breakdown of the HBT 100 according to the present invention is higher than the conventional HBT 200, which indicates improved breakdown-tolerant property.

As described above, the structure according to the present invention achieves a heterojunction bipolar transistor with high breakdown-tolerant property.

More specifically, in the HBT 100, it is preferable that the thickness of the first collector layer 103 is between 5 nm and 50 nm, inclusive. In this case, there is little increase in resistance caused by the first collector layer 103, and thereby the breakdown-tolerant property can be improved while suppressing the characteristic degradation of the HBT 100.

Furthermore, in the first embodiment, the first collector layer 103 is made of disordered n-type InGaP having a disordered structure, of 30 nm in thickness, and doped at a high impurity concentration of 5×10¹⁸ cm⁻³. Here, the impurity concentration of the first collector layer 103 may be at 10^{18th} order, which is an impurity concentration equal to or higher than the impurity concentration of the sub-collector layer 102. In this case, it is possible to reduce the resistance of the first collector layer 103 and to increase the breakdown voltage of the HBT 100 without increasing the collector resistance. Furthermore, the first collector layer 103 also functions as an etching stopper layer when manufacturing the HBT 100, which contributes to raising the yield of the HBT 100.

Furthermore, the first collector layer 103 is made of InGaP having a disordered structure. Accordingly, it is possible to increase the doping efficiency of InGaP, and to increase the impurity concentration of the first collector layer 103. Thus, it is possible to reduce the resistance of the first collector layer 103. Furthermore, it is possible to prevent the location of carrier in InGaP. Thus, it is possible to ease the electric intensity concentration, and to improve the breakdown-tolerant property of the HBT 100.

Furthermore, the first collector layer 103 may be formed with two or more layers having different impurity concentrations. In this case, the first collector layer 103 may be formed of a semiconductor layer made of non-doped or doped InGaP and contacting the sub-collector layer 102, and another semiconductor layer on the semiconductor layer (in the direction of the second collector layer 105) at an impurity concentration higher than the impurity concentration of the InGaP layer. This decreases δEc, and thereby achieving a high-performance heterojunction bipolar transistor.

Here, the first collector layer 103 formed of the two or more layers having different impurity concentrations may have a disordered structure. In this case, the doping efficiency of InGaP increases, and the impurity concentration of the first collector layer 103 can be increased. Thus, it is possible to reduce the resistance of the first collector layer 103. Furthermore, it is possible to prevent the location of carrier in the InGaP. Thus, it is possible to suppress the electric intensity concentration, and to improve the breakdown-tolerant property of the HBT 100.

Furthermore, the HBT 100 can improve the breakdown-tolerant property more effectively when the thickness of the fourth collector layer 104 is 1 nm or more, compared to the case where the thickness is less than 1 nm. Furthermore, in the HBT 100, when the thickness of the fourth collector layer 104 is 50 nm or less, there is be little increase in resistance caused by the fourth collector layer 104 than in the case where the thickness is more than 50 nm. Therefore, the breakdown-tolerant property of the HBT 100 can be improved while suppressing the characteristic degradation.

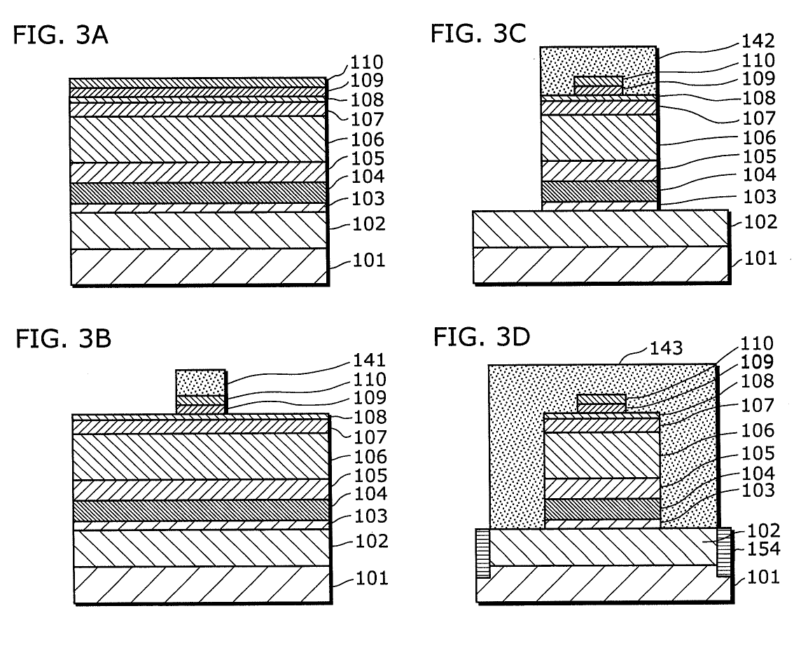

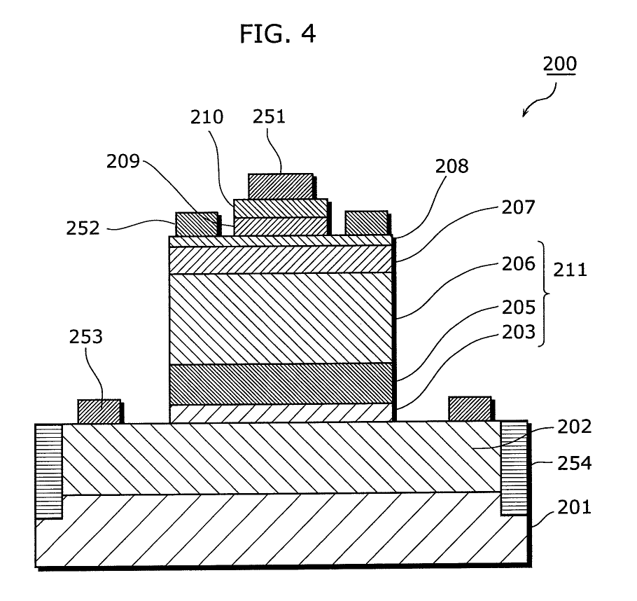

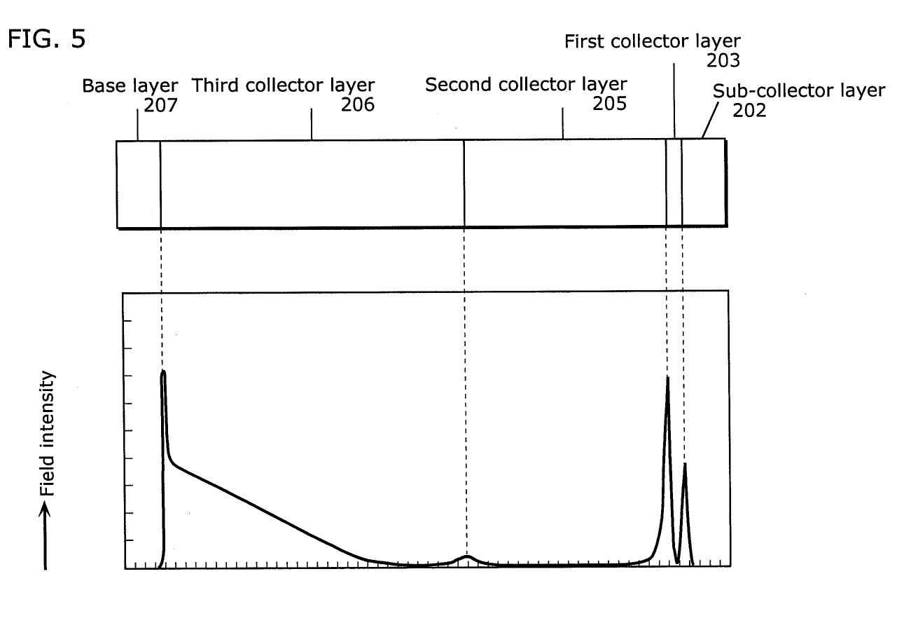

The following is the description for the manufacturing method of the HBT 100 with the above mentioned structure with reference to FIGS. 3A to 3D. FIGS. 3A to 3D are cross-sectional diagrams for describing the manufacturing method of the HBT according to the present invention.

First, as shown in FIG. 3A, on the semi-insulating GaAs substrate 101, the sub-collector layer 102 made of n⁺-type GaAs doped with n-type impurity at a high concentration of 5×10¹⁸ cm⁻³ is stacked using a crystal growth method such as the Molecular Beam Epitaxy (MBE) method or the Metal Organic Chemical Vapor Deposition (MOCVD) method. Subsequently, on the sub-collector layer 102, the following layers are sequentially stacked: the first collector layer 103 made of InGaP of 30 nm in thickness, doped with n-type impurity at an impurity concentration of 5×10¹⁸ cm⁻³; the fourth collector layer 104 made of GaAs of 5 nm in thickness, doped with n-type impurity at an impurity concentration of 1×10¹⁶ cm⁻³; the second collector layer 105 made of GaAs of 400 nm in thickness, doped with n-type impurity at an impurity concentration of 1×10¹⁷ cm⁻³; the third collector layer 106 made of GaAs of 600 nm in thickness, doped with n-type impurity at an impurity concentration of 1×10¹⁶ cm⁻³; and the base layer 107 made of GaAs of 100 nm in thickness, doped with p-type impurity at an impurity concentration of 4×10¹⁹ cm⁻³. Furthermore, the following layers are sequentially formed on the base layer 107: the emitter layer 108 made of InGaP of 50 nm in thickness, doped with n-type impurity at an impurity concentration of 3×10¹⁷ cm⁻³; the emitter cap layer 109 made of GaAs of 200 nm in thickness, doped with n-type impurity at an impurity concentration of 3×10¹⁸ cm⁻³; and the emitter contact layer 110 made of InGaAs of 100 nm in thickness, doped with n-type impurity at an impurity concentration of 1×10¹⁹ cm⁻³.

Next, as shown in FIG. 3B, the emitter island region is covered with the photo resist mask 141, and the emitter island region is formed by sequentially etching a part of the emitter contact layer 110 and a part of the emitter cap layer 109 with a mixture of phosphoric acid, hydrogen peroxide, and water. Here, the emitter layer 108 is hardly etched.

Next, as shown in FIG. 3C, the base island region is covered with another photo resist mask 142, and a part of the emitter layer 108 is selectively etched with hydrochloric acid diluted with water. Subsequently, the base island region is formed by sequentially removing part of the base layer 107, the third collector layer 106, the second collector layer 105 and the fourth collector layer 104 with the mixture of phosphoric acid, hydrogen peroxide, and water using the emitter layer 108 covered with the photo resist mask 142 as a mask.

Note that, the etching for forming the base island region is a selective etching. In the selective etching, only the desired film is removed when multiple film materials are exposed on the surface of the wafer. In this selective etching for forming the base island region, the first collector layer 103 made of InGaP functions as an etching stopper layer. More specifically, the first collector layer 103 made of InGaP stops etching using etchant made of phosphoric acid and hydrogen peroxide. Thus, compared to the conventional technology, accuracy in etching depth can be significantly improved when forming the base island region.

In addition, the etchant used for the selective etching for forming the base island region is different from the etchant used for etching the base layer 107, the third collector layer 106, the second collector layer 105, and the fourth collector layer 104.

The etchant used later selectively etches first collector layer 103 exposed using hydrochloric acid diluted with water. Here, the sub-collector layer 102 made of GaAs functions as the etching stopper layer.

Note that, 5 nm or more is sufficient as the thickness of the first collector layer 103 as an etching stopper layer. Therefore, the first collector layer 103 sufficiently functions as an etching stopper if the thickness is approximately 30 nm.

Next, as shown in FIG. 3D, the device isolation region 154 is formed in order to electrically isolate multiple HBTs manufactured at once (not shown) from other HBTs. More specifically, after the photo resist mask 143 is formed, He ion implantation is performed to the sub-collector layer 102 under an ion implantation condition at an accelerating voltage of 100 keV and a dose amount of 6×10¹³ cm⁻².

Since a manufacturing method to be described hereafter is a general HBT manufacturing method, detailed description shall be omitted. The HBT 100 shown in FIG. 1 is formed through a process of sequentially forming the collector electrode 153, the emitter electrode 151, and the base electrode 152, and a process for forming an insulating film to the structure shown in FIG. 3D.

The HBT 100 is formed as described above.

Note that, in the embodiment above, forming the emitter island region and the base island region, and the etching for the collector layer 111 are performed by wet etching. However, the emitter island region and the base island region may be formed by dry etching. Even in such a case, the selective etching allows forming the HBT 100 described above.

As described above, the manufacturing method described above allows the first collector layer 103 to be formed of semiconductor having etching selectivity to the third collector layer 106 and the second collector layer 105. This allows the first collector layer 103 to function as an etching stopper layer when etching the collector layer 111. As a result, workability by etching can be increased, and thus the HBT 100 can be manufactured at a high reproducibility and a high yield.

### (Variation 1)

In the first embodiment, the first collector layer 103 making up of the HBT 100 is made of GaAs; however, it is not limited to this example. For example, the first collector layer 103 may be made of InGaAs.

In this case, it is preferable that the first collector layer 103 is formed as a semiconductor layer having an impurity concentration equal to or higher than the impurity concentration of the sub-collector 102. Furthermore, it is preferable that the first collector layer 103 is a semiconductor layer having a disordered structure.

Additionally, even when the first collector layer 103 is made of InGaAs, it is preferable that the second collector layer 105, the third collector layer 106, and the fourth collector layer 104 are made of GaAs in the same manner as in the first embodiment.

The structure of the HBT 100 according to the variation 100 is described above.

This structure allows the first collector layer 103 to be made of InGaAs having a small bandgap with GaAs, and thus the conduction band discontinuity (δEc) is not generated in the collector layer 111. Therefore, it is possible to raise the breakdown voltage of the HBT 100 without increasing the collector resistance. Furthermore, it is possible to suppress the deterioration of the high-frequency property of the transistor caused by the carrier accumulation effect and carrier residence effect. More specifically, a high performance HBT 100 can be implemented. Furthermore, the collector electrode 153 can be formed on the InGaAs layer with a small bandgap, and thus it is possible to reduce the contact resistance than in the conventional technology.

Still further, the first collector layer 103 made of InGaAs functions as an etching stopper layer upon manufacturing, and thus it is possible to raise the yield.

### (Variation 2)

The variation 1 describes an example where the first collector layer 103 in the HBT 100 is made of InGaAs. However, it is not limited to this example. For example, the first collector layer 103 may be made of AlGaAs having an impurity concentration equal to or more than the impurity concentration of the sub-collector layer 102.

In this case, that is, even when the first collector layer 103 is made of AlGaAs, it is preferable that the second collector layer 105, the third collector layer 106, and the fourth collector layer 104 are made of GaAs, as described in the first embodiment and the variation 1.

The structure of the HBT 100 according to the variation 2 is as described above.

With this structure, the layer contacting the first collector layer 103 is the fourth collector layer 104 having an impurity concentration lower than that of the second collector layer 105. This suppresses avalanche breakdown that occurs in the interface of the first collector layer 103 opposite to the sub collector layer 102. Therefore, it is possible to implement a heterojunction bipolar transistor with high breakdown-tolerant property.

As described above, according to the present invention, it is possible to achieve the heterojunction bipolar transistor highly tolerant to breakdown and a manufacturing method thereof. More specifically, it is possible to manufacture a heterojunction bipolar transistor with high breakdown-tolerant property compared to the conventional InGaP/GaAs heterojunction bipolar transistor. Accordingly, the heterojunction bipolar transistor according to the present invention shows new possibility as the power amplifier in the terminal transmission unit in the GSM.

Although only an exemplary embodiment of the heterojunction bipolar transistor and the manufacturing method thereof according to this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to heterojunction bipolar transistors, and more particularly, it is applicable to power amplifiers in the terminal transmission unit in the GSM.

What is claimed is:

1. A heterojunction bipolar transistor comprising:
a sub-collector layer;
a collector layer formed on said sub-collector layer and including a first collector layer, a second collector layer, a third collector layer, and a fourth collector layer;
a base layer formed on said collector layer; and
an emitter layer formed on said base layer, said emitter layer being made of semiconductor that has a bandgap larger than semiconductor of which said base layer is made,
wherein said first collector layer is formed on said sub-collector layer, said first collector layer being made of semiconductor different from semiconductor of which said second collector layer, said third collector layer, and said fourth collector layer are made,
said fourth collector layer is formed on said first collector layer, said fourth collector layer having an impurity concentration lower than an impurity concentration of said second collector layer,
said second collector layer is formed on said fourth collector layer, said second collector layer having an impurity concentration lower than an impurity concentration of said sub-collector layer and higher than an impurity concentration of said third collector layer, and
said third collector layer is formed between said second collector layer and said base layer.

2. The heterojunction bipolar transistor according to claim 1,
wherein said first collector layer is made of InGaP and has an impurity concentration equal to or higher than the impurity concentration of said sub-collector layer, and
said second collector layer, said third collector layer, and said fourth collector layer are made of GaAs.

3. The heterojunction bipolar transistor according to claim 2,
wherein said first collector layer is made of InGaP having a disordered structure.

4. The heterojunction bipolar transistor according to claim 2,
wherein said first collector layer is made of two or more layers having different impurity concentrations.

5. The heterojunction bipolar transistor according to claim 1,
wherein said first collector layer is made of InGaAs, and
said second collector layer, said third collector layer, and said fourth collector layer are made of GaAs.

6. The heterojunction bipolar transistor according to claim 1,
wherein said first collector layer is made of AlGaAs and has an impurity concentration equal to or higher than the impurity concentration of said sub-collector layer, and
said second collector layer, said third collector layer, and said fourth collector layer are made of GaAs.

7. The heterojunction bipolar transistor according to claim 1,
wherein said first collector layer has a thickness between 5 nm and 50 nm, inclusive.

8. The heterojunction bipolar transistor according to claim 1,
wherein said fourth collector layer has a thickness of 50 nm or less.

9. The heterojunction bipolar transistor according to claim 8,
wherein said fourth collector layer has a thickness of 1 nm or more.

10. The heterojunction bipolar transistor according to claim 1,
wherein said fourth collector layer is made of two or more layers having different impurity concentrations.

11. The heterojunction bipolar transistor according to claim 1,
wherein the impurity concentration of said fourth collector layer gradually decreases from an interface with said second collector layer to an interface with said first collector layer.

12. The heterojunction bipolar transistor according to claim 1,
wherein said third collector layer is made of two or more layers having different impurity concentrations.

13. The heterojunction bipolar transistor according to claim 1,
wherein the impurity concentration of said third collector layer gradually increases from an interface with said base layer to an interface with said second collector layer.

14. The heterojunction bipolar transistor according to claim 1,
wherein the impurity concentration of said second collector layer ranges from 3×10¹⁶ cm⁻³ to 2×10¹⁷ cm⁻³, and
the impurity concentration of said third collector layer is lower than 3×10¹⁶ cm⁻³.

15. The heterojunction bipolar transistor according to claim 1,
wherein said second collector layer has a thickness of 400 nm or more, and
said third collector layer has a thickness of 600 nm or less.

16. A manufacturing method of a heterojunction bipolar transistor, said manufacturing method comprising:
stacking a sub-collector layer, a collector layer that includes: a first collector layer; a second collector layer; a third collector layer; and a fourth collector layer, a base layer, and an emitter layer, sequentially on a semiconductor substrate; and
etching a part of: the emitter layer; the base layer; and the collector layer, such that a region on the sub-collector layer for forming a collector electrode is exposed;
wherein, in said stacking, the first collector layer is formed on the sub-collector layer, the first collector layer being made of semiconductor different from semiconductor of which the second collector layer, the third collector layer, and the fourth collector layer are made,
the fourth collector layer is stacked on the first collector layer, the fourth collector layer having an impurity concentration lower than an impurity concentration of the second collector layer,
the second collector layer is stacked on the fourth collector layer, the second collector layer having an impurity concentration lower than an impurity concentration of the sub-collector layer and higher than an impurity concentration of the third collector layer,
the third collector layer is stacked between the second collector layer and said base layer, and
the emitter layer is stacked on the base layer, the emitter layer being made of semiconductor with larger bandgap than semiconductor of which the base layer is made.

17. The manufacturing method according to claim 16,
wherein, in said etching,
a part of the first collector layer is etched using an etchant different from an etchant used for etching the third collector layer, the second collector layer, and the fourth collector layer, after etching a part of: the third collector layer; the second collector layer; and the fourth collector layer.

18. The manufacturing method according to claim 16,
wherein, in said stacking,
the first collector layer made of InGaP is stacked, and the second collector layer, the third collector layer, and the fourth collector layer made of GaAs are stacked.

19. The manufacturing method according to claim 16,
wherein, in said stacking,
the first collector layer made of InGaAs is stacked, and the second collector layer, the third collector layer, and the fourth collector layer made of GaAs are stacked.
